(19) United States
(12) Patent Application Publication
(10) Pub. No.: US 2025/0296168 A1
(43) Pub. Date: Sep. 25, 2025

(54) PRINTING RESULT PREDICTION DEVICE AND PRINTING SYSTEM

(71) Applicant: KABUSHIKI KAISHA TOSHIBA, Tokyo (JP)

(72) Inventors: Rina NAGANO, Yokohama Kanagawa (JP); Tatsuya ITAGAKI, Yokohama Kanagawa (JP); Masatoshi TANABE, Yokohama Kanagawa (JP)

(21) Appl. No.: 19/069,549

(22) Filed: Mar. 4, 2025

(30) Foreign Application Priority Data
Mar. 19, 2024 (JP) 2024-044020
Jan. 23, 2025 (JP) 2025-010054

(51) Int. Cl. B23K 3/06; B23K 101/42; B41F 15/08; B41F 15/14; B41F 33/02; H05K 3/12

(52) U.S. Cl. CPC B23K 3/0638; B41F 15/0813; B41F 15/14; B41F 33/025; H05K 3/1233; B23K 2101/42

(57) ABSTRACT

A printing result prediction device is configured to predict a volume of solder paste printed by a printer onto a substrate. The printer is configured to print the solder paste by filling the solder paste into a stencil aperture of a stencil disposed on the substrate. The printing result prediction device includes a calculation part. The calculation part is configured to input a printing condition to a prediction model trained by machine learning, and predict a volume of solder paste printed by the stencil aperture of the stencil in a next printing using the input printing condition. The printing condition includes stencil information related to the stencil used to print, solder paste information related to the solder paste used to print, substrate information including unevenness information related to a protrusion on the substrate used to print, and a printing parameter of an operation of the printer when printing.

### CROSS-REFERENCE TO RELATED APPLICATIONS

This application is based upon and claims the benefit of priority from Japanese Patent Application No. 2024-044020, filed on Mar. 19, 2024; and No. 2025-010054, filed on Jan. 23, 2025; the entire contents of which are incorporated herein by reference.

### FIELD

Embodiments described herein relate generally to a printing result prediction device and a printing system.

### BACKGROUND

The manufacturing of a surface mounting substrate includes a stencil printing process of a printer printing solder paste on a substrate, a pick and place process of a pick and place machine mounting a component on the substrate, and a reflow process of a reflow oven bonding the component and the substrate by heating.

The operation of the printer in the stencil printing process is specified by printing parameters of the printer. The volume of the solder paste printed on the substrate changes according to a printing condition such as the printing parameters of the printer, etc. In such a stencil printing process, defects may occur in which the volume of the printed solder paste is excessive or insufficient.

### BRIEF DESCRIPTION OF THE DRAWINGS

FIG. 1 is a block diagram illustrating a printing system including a printing result prediction device according to an embodiment;

FIGS. 2A and 2B are schematic plan views illustrating a substrate and a stencil used in the stencil printing process;

FIGS. 3A to 3C are schematic cross-sectional views illustrating the stencil printing process performed by the printer;

FIG. 4 is a schematic view illustrating a prediction performed by the printing result prediction device according to the embodiment;

FIGS. 5A to 5H are schematic cross-sectional views describing the stencil printing process;

FIGS. 6A to 6H are schematic cross-sectional views describing the stencil printing process;

FIG. 7 is a schematic view illustrating image entropy including silkscreen information;

FIG. 8 is a schematic cross-sectional view illustrating the stencil printing process performed by the printer;

FIG. 9 is a graph illustrating the accuracy success rate of the prediction result of the volume of the solder paste to be printed;

FIG. 10 is a schematic view illustrating a modification of the prediction performed by the printing result prediction device according to the embodiment;

FIG. 11 is a schematic view illustrating a prediction performed by the result prediction device according to the embodiment;

FIG. 12 is a schematic plan view illustrating a portion of the substrate;

FIGS. 13A and 13B are schematic plan views illustrating portions of the substrate;

FIG. 13C is a graph illustrating an unevenness of the substrate;

FIG. 14 is a schematic view illustrating a substrate and a stencil in the stencil printing process;

FIG. 15 is a graph illustrating the relationship between the distance between a protrusion and a pad and the increase rate of the volume of solder paste;

FIG. 16 is a schematic view illustrating another example of a prediction performed by the result prediction device according to the embodiment;

FIG. 17 is a graph illustrating the prediction error of the volume of the printed solder paste;

FIG. 18 is an enlarged schematic plan view illustrating a portion of the substrate;

FIG. 19 is a schematic view illustrating training of a prediction model;

FIG. 20 is a schematic view illustrating an operation of a printing system according to an embodiment; and

FIG. 21 is a schematic view illustrating a configuration of the printing result prediction device according to the embodiment.

### DETAILED DESCRIPTION

A printing result prediction device according to one embodiment, is configured to predict a volume of solder paste printed by a printer onto a substrate. The printer is configured to print the solder paste by filling the solder paste into a stencil aperture of a stencil disposed on the substrate. The printing result prediction device includes a calculation part. The calculation part is configured to input a printing condition to a prediction model trained by machine learning, and predict a volume of solder paste printed by the stencil aperture of the stencil in a next printing using the input printing condition. The printing condition includes stencil information related to the stencil used to print, solder paste information related to the solder paste used to print, substrate information including unevenness information related to a protrusion on the substrate used to print, and a printing parameter of an operation of the printer when printing.

Various embodiments are described below with reference to the accompanying drawings.

In the specification and drawings, components similar to those described previously or illustrated in an antecedent drawing are marked with like reference numerals, and a detailed description is omitted as appropriate.

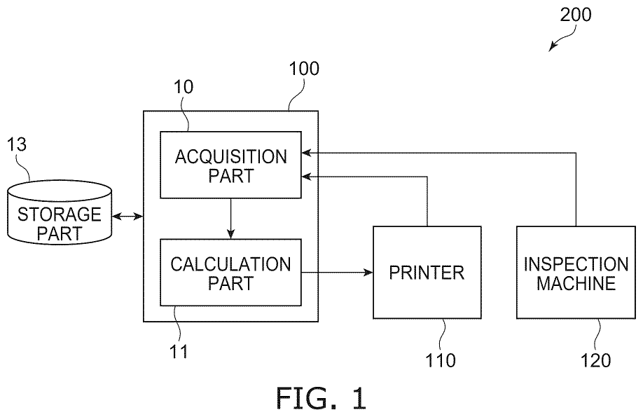

FIG. 1 is a block diagram illustrating a printing system including a printing result prediction device according to an embodiment.

As illustrated in FIG. 1, the printing system 200 according to the embodiment includes a printing result prediction device 100, a printer 110, and an inspection machine 120.

The printer 110 performs a stencil printing process of printing solder paste on a substrate. The printer 110 repeatedly performs the stencil printing process. In other words, the printer 110 prints solder paste on multiple substrates by sequentially performing the stencil printing process on the multiple substrates. The inspection machine 120 inspects the shape and the amount (the volume) of the solder paste printed on the substrate by the printer 110, as well as the height of the solder paste, the presence of defects, etc.

The printing result prediction device 100 is an information processing device (an information processing system) that predicts the volume of the solder paste printed on the substrate by the stencil printing process of the printer 110.

The printing result prediction device 100 includes an acquisition part 10 and a calculation part 11. The acquisition part 10 acquires information from outside the printing result prediction device 100. For example, the acquisition part 10 includes a communication module for communicating with external devices, a communication interface, connection terminals, etc. For example, the acquisition part 10 is communicatably connected with external devices such as the printer 110, the inspection machine 120, etc., and receives information from the external devices. Any wired, wireless, or other technique can be used to communicate. The acquisition part 10 also may include an input interface (a keyboard, a touch panel, etc.) for a user to input information to the printing result prediction device 100. The acquisition part 10 accepts the input of the information by the user. Thus, the acquisition part 10 acquires various information. The calculation part 11 is configured to communicate with the acquisition part 10 and can acquire the information acquired by the acquisition part 10.

The calculation part 11 or the acquisition part 10 may be communicatably connected with a storage part 13 (a storage device). For example, the storage part 13 stores information of the substrate, information of the stencil, a prediction model used to predict the volume of the solder paste to be printed, etc. The calculation part 11 can acquire the information stored in the storage part 13. The storage part 13 may be a part of the printing result prediction device 100.

For example, the calculation part 11 calculates, based on the information acquired from at least one of the printer 110, the inspection machine 120, or the storage part 13, the predicted value of the volume of the solder paste printed on the substrate by the stencil printing process. Specifically, the calculation part 11 inputs a printing condition to a prediction model, and predicts the volume of the solder paste to be printed when performing the next stencil printing process using the input printing condition.

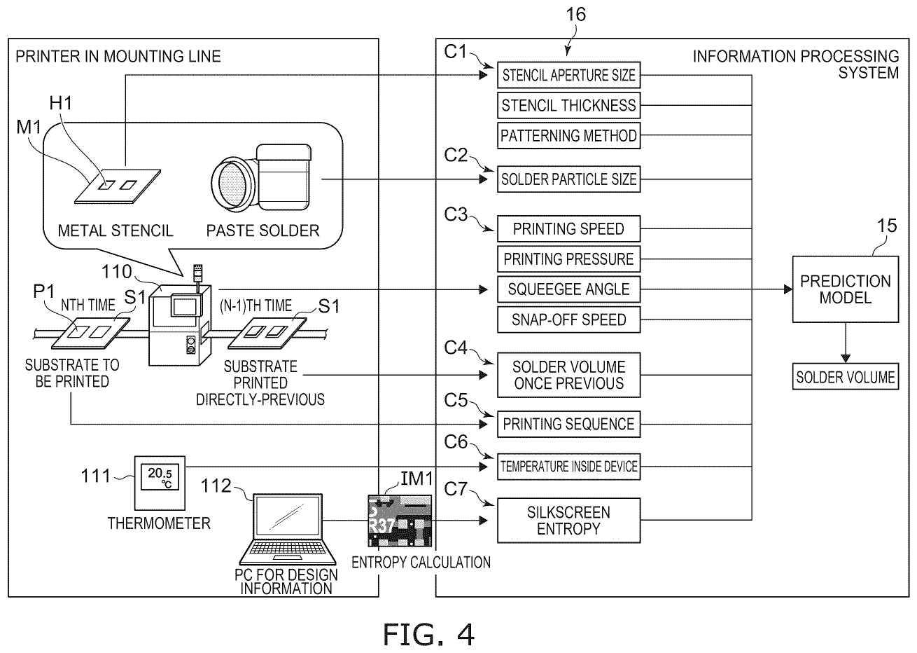

The printing condition is a combination of various parameters of features of the stencil printing process. To perform the stencil printing process using the input printing condition means, in other words, to perform the stencil printing process having the features of the parameters of the printing condition. The details of the input printing condition are described below with reference to FIG. 4.

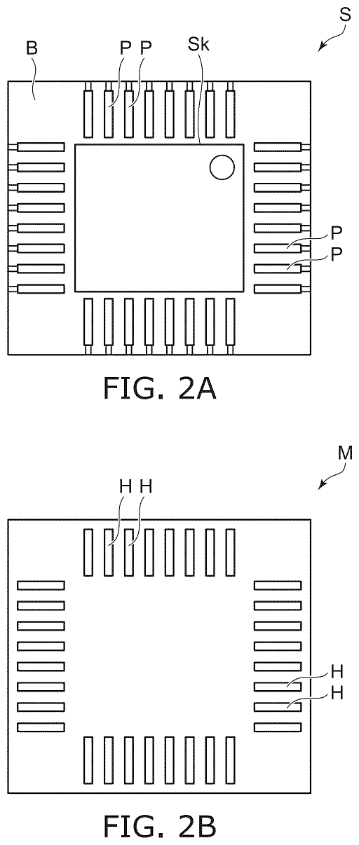

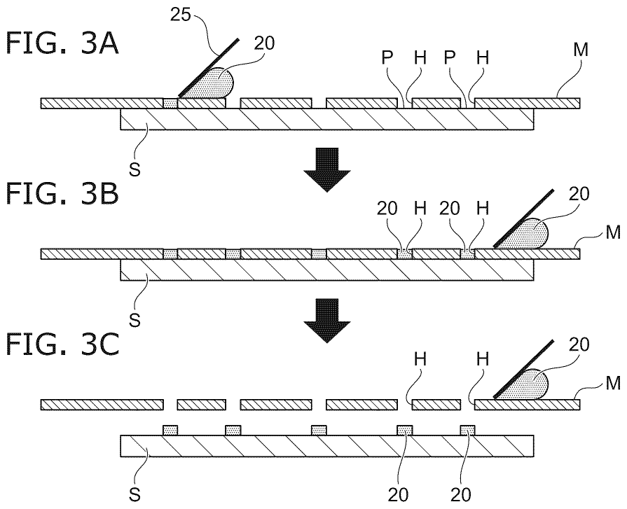

The stencil printing process of the printer 110 will now be described with reference to FIGS. 2A to 3C.

FIGS. 2A and 2B are schematic plan views illustrating a substrate and a stencil used in the stencil printing process.

FIG. 2A illustrates a portion of a substrate S on which the printer 110 prints solder paste. FIG. 2B illustrates a portion of a stencil M used to print the solder paste on the substrate S.

As illustrated in FIG. 2A, the substrate S includes a base member B and pads P (conductive parts). The base member B is, for example, an insulating layer including an insulator such as a resin, etc. Wiring parts formed of metal are located inside the substrate S. The pads P are electrically connected with the wiring parts located inside the substrate S, and are exposed at the surface of the substrate S. The pads P are, for example, copper foil. Multiple pads P are located on one substrate S.

A silkscreen Sk may be printed at the surface of the substrate S as necessary. The silkscreen Sk is, for example, ink printed on the substrate and is shaped as characters, symbols, or figures. For example, the silkscreen Sk displays information of the substrate S and/or information (a model number, component orientation, etc.) related to a component mounted to the substrate S.

As illustrated in FIG. 2B, the stencil M is, for example, a plate-shaped metal stencil in which multiple stencil apertures H (holes) are provided. The position and shape of each stencil aperture H corresponds to the position and shape of each pad P of the substrate S. In the stencil printing process, solder paste is adhered onto the pads P corresponding respectively to the stencil apertures H by filling the solder paste into the stencil apertures H.

FIGS. 3A to 3C are schematic cross-sectional views illustrating the stencil printing process performed by the printer.

As illustrated in FIG. 3A, the stencil M that corresponds to the substrate S is disposed on the substrate S to be printed. As a result, the surface of the substrate S is covered with the stencil M. At this time, the pads P that correspond to the stencil apertures H are exposed at the stencil apertures H of the stencil M.

Solder 20 in paste form is disposed on the stencil M. A squeegee 25 is moved along the upper surface of the stencil M in contact with the upper surface of the stencil M. As a result, the solder paste 20 on the stencil M is spread and coated over the stencil M by the squeegee 25.

As illustrated in FIG. 3B, the solder paste 20 is filled into the stencil apertures H of the stencil M by coating the solder paste 20 on the stencil M.

As illustrated in FIG. 3C, the stencil M is released from the substrate S. As a result, the solder paste 20 that is filled into the stencil apertures H of the stencil M is transferred onto the pads P of the substrate S. Thus, the solder paste 20 is printed on the substrate S. In other words, a layer of the solder paste 20 is formed in a shape corresponding to the stencil apertures H.

For example, the printer 110 uses one stencil M to sequentially implement such a stencil printing process on the multiple substrates S. As a result, the printer 110 sequentially prints solder paste on the multiple substrates S.

Mechanisms that transport the substrates and/or stencil, move the squeegee, and coat the solder paste can be realized by appropriately using drive devices such as actuators including motors, etc. For example, the control circuit of the printer 110 controls the operations of the drive devices and causes the drive devices to perform the operations specified by the printing parameters.

The inspection machine 120 detects the volume of the solder paste 20 printed on the pads P by the stencil apertures H. For example, the inspection machine 120 optically measures the shape (the height and/or area) of the solder paste 20 on each pad P and calculates the volume of the solder paste 20 on each pad P. For example, the inspection machine 120 irradiates light on the solder paste 20 and measures the reflected light. The inspection machine 120 is not limited thereto; it is sufficient for the inspection machine 120 to detect the volume of the solder paste 20 using any technique.

FIG. 4 is a schematic view illustrating a prediction performed by the printing result prediction device according to the embodiment.

For example, the printer 110 performs the stencil printing process of printing solder paste on a pad P1 of a substrate S1 by filling the solder paste into a stencil aperture H1 of a stencil M1 disposed on the substrate S1. The substrate S1, the stencil M1, the stencil aperture H1, and the pad P1 are, respectively, examples of the substrate S, the stencil M, the stencil aperture H, and the pad P described above.

As described above, the printer 110 repeatedly performs the stencil printing process. The inspection machine 120 (see FIG. 1) outputs volume information C4 of the volume of the solder paste printed on the substrate S1 by the stencil aperture H1 of the stencil M1 in the previous stencil printing process (the (N−1)th time, wherein N is an integer not less than 2) using the stencil M1. The acquisition part 10 of the printing result prediction device 100 (see FIG. 1) acquires the volume information C4.

The calculation part 11 of the printing result prediction device 100 (see FIG. 1) inputs a printing condition 16 to a prediction model 15 and predicts the volume of the solder paste to be printed on the substrate S1 by the stencil aperture H1 of the stencil M1 when the next stencil printing process (following the previous stencil printing process) is performed using the stencil M1 with the input printing condition 16. In other words, the calculation part 11 inputs the printing condition 16 to the prediction model 15, and outputs a predicted value of the volume of the solder paste to be printed on the substrate S1 by the stencil aperture H1 of the stencil M1 by performing the Nth stencil printing process (the next stencil printing process) using the stencil M1. The prediction model 15 is a machine learning model pretrained by machine learning using the volume of solder paste printed previously.

As illustrated in FIG. 4, the input printing condition 16 includes (1) stencil information C1 related to the stencil M1 used in the stencil printing process, (2) solder paste information C2 related to the solder paste used in the stencil printing process, (3) a printing parameter C3 indicating an operation of the printer 110 in the stencil printing process, (4) the volume information C4 of the volume of the solder paste printed by the stencil aperture H1 of the stencil M1 in the previous stencil printing process, and (5) a printing sequence C5 indicating the number of uses of the stencil M1 in the stencil printing process. The printing condition 16 may further include (6) environmental information C6 of the stencil printing process, and (7) substrate information C7 related to the substrate S1 used in the stencil printing process.

The stencil information C1 includes, for example, the thickness of the stencil M1 and the size (the area) of the stencil aperture H1. The stencil information C1 may include a coordinate of the stencil aperture H1. The stencil information C1 may include information of the patterning method of the stencil M1. The stencil information C1 may include an angle (a taper angle) of the side surface of the stencil aperture H1. The stencil information C1 may include the material of the stencil M1. The stencil information C1 may include rigidity information of the stencil M1 such as the Young's modulus, etc. The patterning method is, for example, the method for providing the stencil apertures H1 in the stencil M1 such as laser patterning, etching, etc. For example, the calculation part 11 reads the stencil information C1 from the storage part 13 (see FIG. 1). Or, the stencil information C1 (or the model number of the stencil M1 used, etc.) may be input to the calculation part 11 from outside the printer 110, etc., via the acquisition part 10.

The solder paste information C2 includes, for example, information of the particle size of the solder paste. The particle size of the solder paste is, for example, the average value of the particle size of the solder paste used in the stencil printing process. The solder paste information C2 may include information such as fluctuation of the particle size of the solder paste, the viscosity thixotropic index and/or flux content of the solder paste, etc. For example, the calculation part 11 reads the solder information C2 from the storage part 13. Or, the solder paste information C2 (or the model number of the solder paste used, etc.) may be input to the calculation part 11 from outside the printer 110, etc., via the acquisition part 10. Or, the solder paste information C2 may be separately estimated by an estimation system.

The printing parameter C3 includes, for example, the speed (the printing speed) of moving the squeegee 25 along the stencil M1, the pressure (the printing pressure) causing the squeegee 25 to contact the stencil M1, the angle (the squeegee angle) of the squeegee 25 with respect to the stencil M1, and the speed (the snap-off speed) of releasing the substrate S1 from the stencil M1. The printing parameter C3 may include the distance (the clearance) between the stencil M1 and the substrate S1. The printing parameter C3 may include the frequency of automatically cleaning the stencil (the cleaning frequency). The printing parameter C3 is, for example, a combination of multiple parameters such as the printing speed, the printing pressure, etc.

The printing parameter C3 that is input to the prediction model 15 is, for example, a candidate of the printing parameter C3 in the next stencil printing process. For example, the calculation part 11 acquires the printing parameter C3 from the printer 110 or the storage part 13. For example, the calculation part 11 acquires multiple parameters indicating operations that can be performed by the printer 110 from the printer 110 or the storage part 13, and selects the printing parameter C3 (the candidate of the printing parameter C3 in the next stencil printing process) to be input to the prediction model 15 from among the acquired multiple parameters.

The volume information C4 is information acquired from the inspection machine 120 by the acquisition part 10. The scope of “the volume of the solder paste” for the calculation part 11 and the input and output of the prediction model 15 includes values of indicators corresponding to the volume of the solder paste. Specifically, for example, the printing transfer efficiency and/or a numerical value convertible to the volume of the solder paste may be used. The printing transfer efficiency is the ratio of the volume of the solder paste printed by the stencil aperture H to the volume of the stencil aperture H (the hole) of the stencil.

The printing sequence C5 is the number of uses of the stencil M1 in the stencil printing process. Specifically, the printing sequence C5 that is input is information indicating how many times the stencil M1 will have been used after the next stencil printing process is performed. In other words, the printing sequence C5 that is input is information indicating that the stencil printing process will be using the stencil M1 for the Nth time. For example, the calculation part 11 acquires the number of uses of the stencil M1 from the printer 110 via the acquisition part 10. Or, the calculation part 11 may count the number of uses of the stencil M1 by the printer 110 inputting a signal to the calculation part 11 to indicate that the stencil printing process is being performed.

The environmental information C6 includes, for example, the temperature and/or humidity inside the printer 110. The environmental information C6 may include vibrations of the printer 110. For example, the temperature and/or humidity inside the printer 110 are measured by a thermometer 111 and/or a hygrometer provided for the printer 110. Or, the temperature and/or humidity inside the printer 110 may be measured by the thermometer 111 and/or a hygrometer included in the printer 110. For example, the vibrations of the printer 110 are measured by a vibrometer located in the printer 110. The calculation part 11 acquires the temperature and/or humidity measured by the thermometer 111 and/or a hygrometer and the vibrations measured by the vibrometer via the acquisition part 10.

The substrate information C7 includes silkscreen information related to a silkscreen located at the substrate S1. In the example, the silkscreen information is image entropy calculated based on an image of the substrate S1 displaying the position and/or shape of the silkscreen. Details of the image entropy are described below. The substrate information C7 is not limited to silkscreen information and may include the thickness and/or number of layers of the substrate S1, the thickness of the copper foil of the pad P1, etc. The substrate information C7 may include a coating region of a solder resist liquid to be coated onto the surface of the substrate S1. The substrate information C7 may include the warp state of the substrate S1. For example, the substrate information C7 such as the silkscreen information, etc., is input to the calculation part 11 via the acquisition part 10 from an external device 112 (a computer or a storage device) that stores the design information of the substrate S1. Or, for example, an image of the substrate S1 may be input from the external device 112 to the calculation part 11; and the image entropy may be calculated based on the image acquired by the calculation part 11. The calculation part 11 may read the substrate information C7 and/or the image of the substrate S1 from the storage part 13.

The printing condition 16 also may include the thickness of the squeegee 25 used to print, the length of the squeegee 25, and the exposed width of the squeegee 25, the material of the squeegee 25, rigidity information of the squeegee 25 such as the Young's modulus, etc. The printing condition 16 may include the elapsed time after replenishing the solder paste in the printer 110, the solder paste amount on the stencil M1, the tension of the stencil M1, etc. The printing condition 16 may include the type and/or position of the jig supporting the substrate S1 to be printed from below.

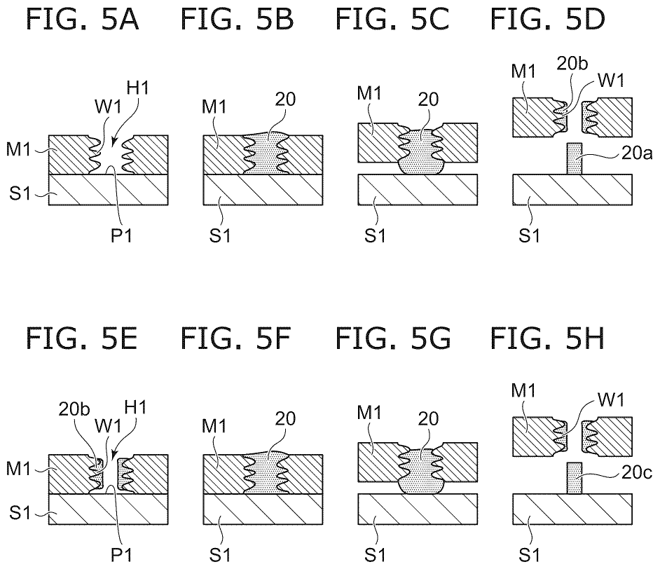

FIGS. 5A to 5H are schematic cross-sectional views describing the stencil printing process.

FIGS. 5A to 5D are an example of the (N−1)th stencil printing process using the stencil aperture H1 of the stencil M1.

As illustrated in FIG. 5A, there are cases where a side surface W1 of the stencil aperture H1 of the stencil M1 includes an unevenness. For example, there are cases where the side surface W1 becomes rough due to the patterning method of the stencil aperture H1 when manufacturing the stencil M1.

The solder paste 20 is filled into the stencil aperture H1 as illustrated in FIG. 5B, and then the stencil M1 is released from the substrate S1 as in FIG. 5C. As a result, as illustrated in FIG. 5D, a portion 20a of the solder paste 20 filled into the stencil aperture H1 is printed on the pad P1 of the substrate S1. Another portion 20b of the solder paste 20 filled into the stencil aperture H1 is adhered to the side surface W1 of the stencil M1. For example, the amount of the portion 20b of the solder paste 20 adhered to the side surface W1 changes according to the shape of the side surface W1 including the roughness, the unevenness, etc. It is therefore considered that the volume of the solder paste 20 printed on the substrate S1 (the volume of the portion 20a) reflects the shape of the side surface W1. The volume information C4 described with reference to FIG. 4 is, for example, the volume of the portion 20a of the solder paste 20 filled into the stencil aperture H1. Accordingly, the volume information C4 reflects the shape of the side surface W1 including the roughness, the unevenness, etc.

FIGS. 5E to 5H are an example of the Nth stencil printing process using the stencil aperture H1 of the stencil M1. The Nth stencil printing process prints solder paste on the pad P1 of a different substrate S1 from the (N−1)th stencil printing process.

In the Nth stencil printing process as illustrated in FIG. 5E, the portion 20b of the solder paste 20 adhered in the (N−1)th stencil printing process remains on the side surface W1 of the stencil aperture H1. New solder paste 20 is filled into such a stencil aperture H1 as illustrated in FIG. 5F, and then the stencil M1 is released from the substrate S1 as illustrated in FIG. 5G. As a result, a portion 20c of the solder paste 20 filled into the stencil aperture H1 is printed on the substrate S1 as illustrated in FIG. 5H. An amount of the solder paste 20 corresponding to the shape of the side surface W1 including the roughness, the unevenness, or the like is adhered to the side surface W1 of the stencil aperture H1.

Thus, information of the shape of the side surface W1 of the stencil aperture H1 including the roughness, unevenness, etc., can be obtained based on the volume (i.e., the volume information C4) of the solder paste 20 printed in the (N−1)th stencil printing process. The volume of the solder paste 20 (the volume of the portion 20c) printed on the pad P1 of the substrate S1 in the Nth stencil printing process changes according to the shape of the side surface W1.

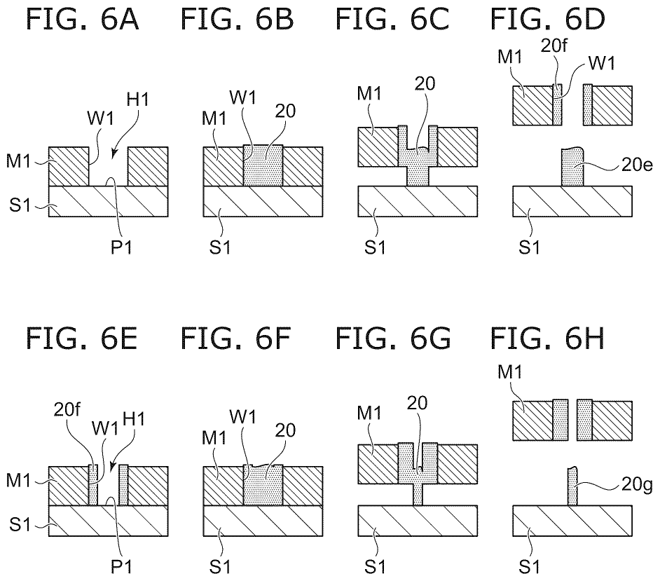

FIGS. 6A to 6H are schematic cross-sectional views describing the stencil printing process.

FIGS. 6A to 6D are an example of the (N−1)th stencil printing process using the stencil aperture H1 of the stencil M1. As in FIG. 6A, the stencil M1 is disposed on the substrate S1. The solder paste 20 is filled into the stencil aperture H1 of the stencil M1 as in FIG. 6B, and the stencil M1 is released from the substrate S1 as in FIG. 6C. As a result, as in FIG. 6D, a portion 20e of the solder paste 20 filled into the stencil aperture H1 is printed on the pad P1 of the substrate S1. Another portion 20f of the solder paste 20 filled into the stencil aperture H1 is adhered to the side surface W1 of the stencil M1.

FIGS. 6E to 6H are an example of the Nth stencil printing process using the stencil aperture H1 of the stencil M1. As in FIG. 6E, the stencil M1 is disposed on the substrate S1. In the Nth stencil printing process, the portion 20f of the solder paste 20 adhered in the (N−1)th stencil printing process remains on the side surface W1 of the stencil aperture H1. New solder paste 20 is filled into such a stencil aperture H1 as illustrated in FIG. 6F, and then the stencil M1 is released from the substrate S1 as illustrated in FIG. 6G. As a result, as illustrated in FIG. 6H, a portion 20g of the solder paste 20 filled into the stencil aperture H1 is printed on the substrate S1. More of the solder paste 20 adheres to the side surface W1 of the stencil aperture H1.

Thus, by repeating the stencil printing process, the volume of the solder paste 20 adhered to the side surface W1 of the stencil aperture H1 changes. For example, as the number of stencil printing processes performed increases, that is, as the number of uses of the stencil M1 increases, the volume of the solder paste 20 adhered to the side surface W1 increases, and the volume of the solder paste 20 printed on the substrate S1 decreases.

The state of the side surface W1, e.g., information of the amount of the solder paste 20 adhered to the side surface W1, can be obtained based on the number of uses (i.e., the printing sequence C5) of the stencil M1. The volume of the solder paste 20 printed on the substrate S1 by the stencil aperture H1 changes according to the state of the side surface W1.

According to the embodiment as described above, the volume information C4 and the printing sequence C5 in addition to the stencil information C1, the solder paste information C2, and the printing parameter C3 are input to the prediction model 15. As a result, for example, the volume of the solder paste to be printed can be predicted by considering the state of the side surface W1 such as the shape (the unevenness and/or roughness) of the side surface W1 of the stencil M1 and/or the dirt (e.g., the amount of adhered solder paste) on the side surface W1. According to the embodiment, the prediction accuracy of the volume of the solder paste to be printed can be increased.

For example, it is difficult to directly measure the shape of the side surface W1 of the stencil M1 and the amount of the solder paste adhered to the side surface W1. In contrast, according to the embodiment, the information related to the state of the side surface W1 of the stencil M1 can be easily obtained by using the volume information C4 and the printing sequence C5.

For example, the solder paste that is adhered to the side surface W1 is removed by cleaning the stencil M1. The number of uses of the stencil M1 indicated by the printing sequence C5 is, for example, the number of uses after cleaning the stencil M1, and is reset to zero by cleaning the stencil M1.

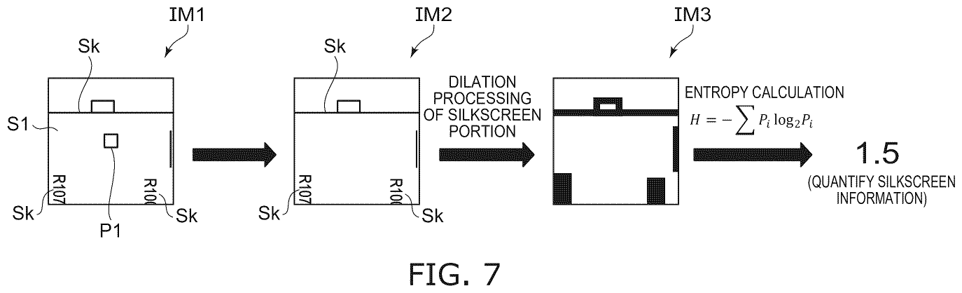

FIG. 7 is a schematic view illustrating image entropy including silkscreen information.

For example, the silkscreen information included in the substrate information C7 described with reference to FIG. 4 is based on an image IM1 of the substrate S1. The image IM1 displays the pad P1 and the periphery of the pad P1.

In the example, the silkscreen information is information of the silkscreen Sk at the periphery of the pad P1. That is, the silkscreen information is related to the position and shape of the silkscreen at the periphery of the pad on which the solder paste is printed by the stencil aperture of the stencil used in the stencil printing process.

The periphery of the pad on which the solder paste is printed is an area of a prescribed size at the periphery of the pad. The periphery of the pad on which the solder paste is printed is, for example, a square region that is about 1 to 10 cm each side and is centered on the center of the pad. The image IM1 may be, for example, an image acquired by imaging the substrate S1, or may be a design drawing of the substrate S1.

For example, the silkscreen information is image entropy of an image displaying information of the silkscreen Sk at the periphery of the pad P1. For example, as illustrated in FIG. 7, an image IM2 is derived by extracting only the image of the silkscreen Sk from the image IM1. The image IM2 may be subjected to binarization processing. In binarization, the pixels that display the image of the silkscreen Sk are set to black; and the other pixels are set to white. For example, an image IM3 is derived by performing dilation processing of the image IM2 multiple times. In dilation processing, the pixels that are adjacent to the image of the silkscreen Sk displayed by black pixels in the image IM2 are replaced with black.

The image entropy of the image IM3 can be used as the silkscreen information. The image entropy (H) is calculated by the formula H=−τPᵢ log₂Pᵢ. Here, i is an index representing the gradation of the pixel value. Pᵢ is the appearance probability of a pixel of the ith gradation in the image. The image entropy (H) is calculated based on the sum total over i.

The dilation processing of deriving the image IM3 is omissible as appropriate and may be performed as necessary. For example, the image entropy of the image IM2 may be used as the silkscreen information.

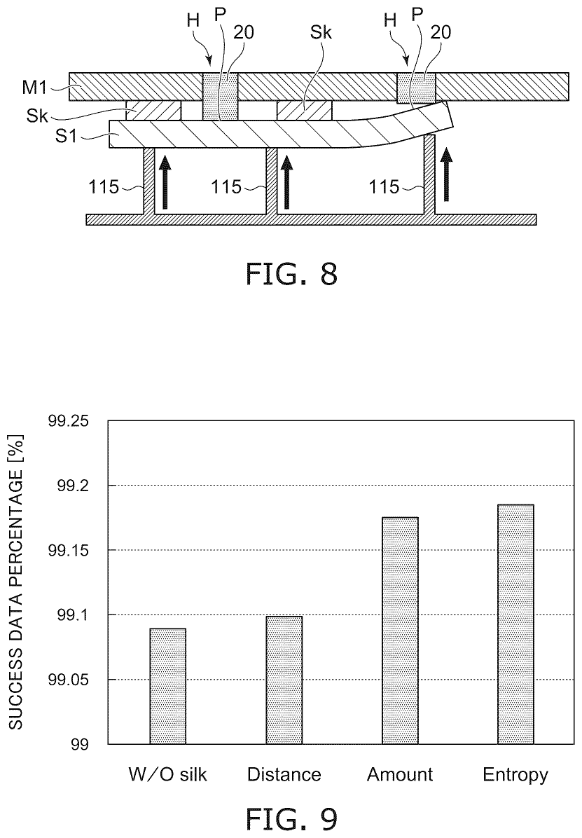

FIG. 8 is a schematic cross-sectional view illustrating the stencil printing process performed by the printer.

In the stencil printing process as illustrated in FIG. 8, for example, the stencil M1 is disposed on the substrate S1 on which the silkscreen Sk is printed. The substrate S1 is supported by multiple pins 115 at multiple positions.

The silkscreen Sk is a protrusion protruding upward from the surface of the substrate S1. The silkscreen Sk is positioned between the stencil M1 and the substrate S1. When such a silkscreen Sk is present, for example, there are cases where the substrate S1 is bent by forces from a jig such as the pins 115, etc. When the substrate S1 is bent, the distances between the substrate S1 and the pads P are different for each pad P according to the position and/or shape of the silkscreen Sk around the pad P. As a result, the amount of the solder paste 20 filled into the stencil aperture H on the pad P is different for each pad P. That is, there are cases where the volume of the solder paste printed on the pad P is different according to the position and/or shape of the silkscreen Sk.

In contrast, according to the embodiment, the printing condition 16 that is input to the prediction model 15 may include the silkscreen information as described above. By considering the silkscreen information, the prediction accuracy can be further increased by predicting the volume of the solder paste to be printed.

FIG. 9 is a graph illustrating the accuracy success rate of the prediction result of the volume of the solder paste to be printed.

To calculate the success data percentage illustrated in FIG. 9, the values of the volumes of the solder paste printed on the pads P by the stencil apertures H of the stencil M are predicted by the prediction model 15. Also, the volumes of the solder paste printed on the pads P by the stencil apertures H are measured. The success data percentage is the ratio of the number of values for which the prediction error is less than a prescribed value (a specification value) to the total number of predicted values. The prediction error is a value corresponding to the difference between the actual measured value of the volume of the solder paste and the predicted value of the volume of the solder paste.

In FIG. 9, “W/O silk” is data when the printing condition 16 input to the prediction model 15 does not include the silkscreen information. “Distance”, “Amount”, and “Entropy” are data when the printing condition 16 input to the prediction model 15 includes the silkscreen information. For “Distance”, the silkscreen information is the distance between the pad P and the silkscreen Sk most proximate to the pad P. For “Amount”, the silkscreen information is the amount (e.g., the area) of the silkscreen Sk at the periphery of the pad P. For “Entropy”, the silkscreen information is the image entropy described with reference to FIG. 7.

As illustrated in FIG. 9, the prediction accuracy can be further increased by considering the silkscreen information. The prediction accuracy can be even further increased when the silkscreen information includes the image entropy calculated based on the image of the substrate.

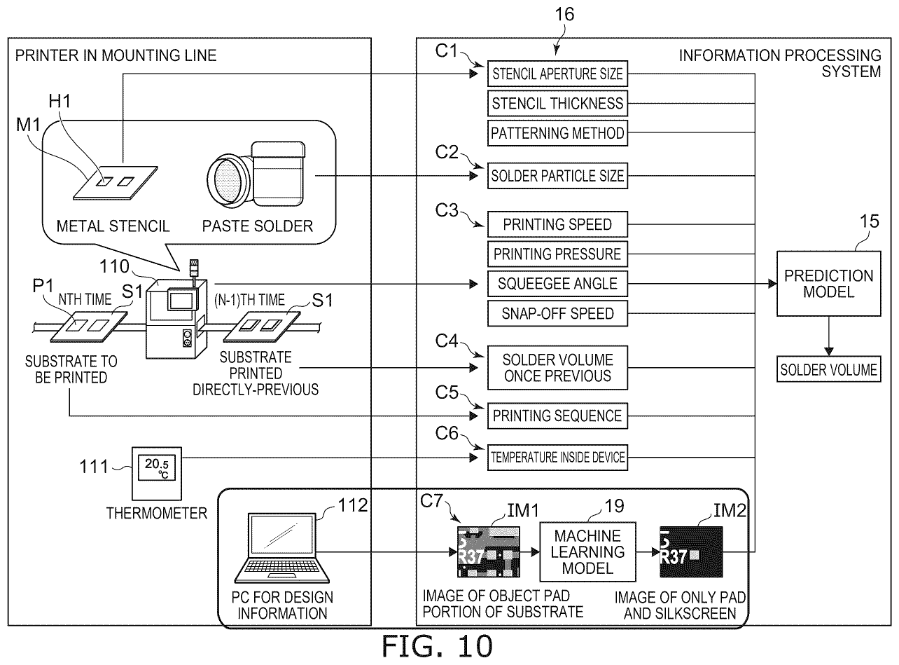

FIG. 10 is a schematic view illustrating a modification of the prediction performed by the printing result prediction device according to the embodiment.

In the example of FIG. 4 above, the silkscreen information of the substrate information C7 includes the image entropy. The example of FIG. 10 differs from the example described with reference to FIG. 4 in that the substrate information C7 includes an image of the substrate S1 instead of the image entropy.

As illustrated in FIG. 10, the image IM1 that displays the pad P1 on which the solder paste is printed, for which the volume will be predicted, and the periphery of the pad P1 may be input as the substrate information C7. Or, the image IM2 that displays only the image of the pad P1 and the silkscreen Sk may be generated based on the image IM1; and the image IM2 may be input as the substrate information C7. For example, the image IM2 may be generated by a machine learning model 19 trained to output the image IM2 based on the input of the image IM1.

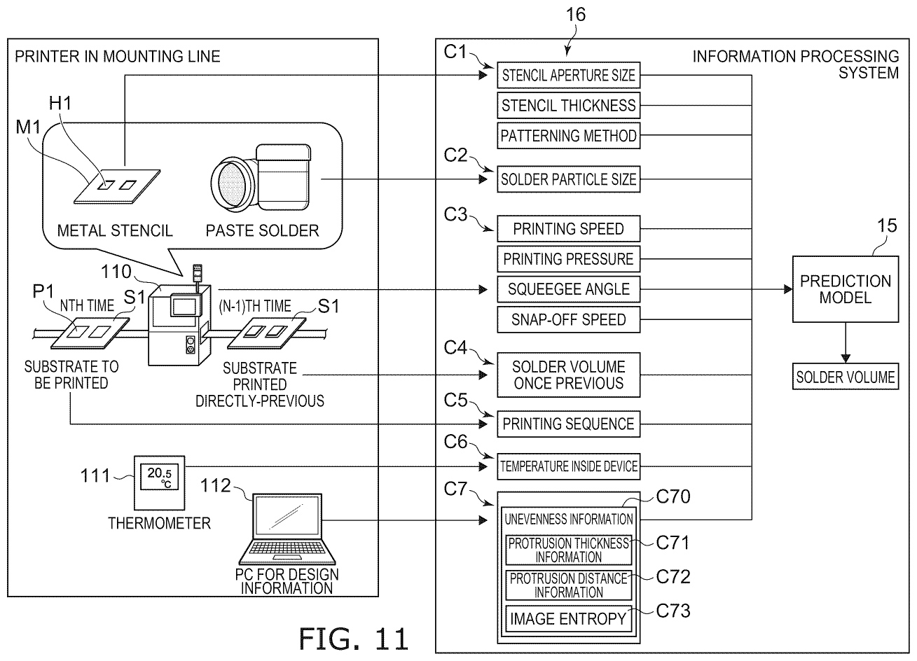

FIG. 11 is a schematic view illustrating a prediction performed by the result prediction device according to the embodiment.

The example illustrated in FIG. 11 differs from the example described with reference to FIG. 4 in that unevenness information C70 is used as the substrate information C7.

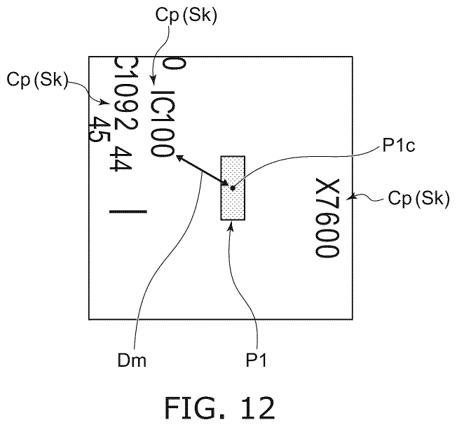

Multiple protrusions Cp (see FIG. 12, etc.) are located on the surface of the substrate S1. The unevenness information C70 is information related to the protrusions Cp located on the substrate S1. More specifically, the unevenness information includes at least one of thickness information C71 related to the thickness of the protrusions Cp, distance information C72 corresponding to the distance between the pad P1 and the protrusions Cp, or image entropy C73 calculated based on an image including the protrusions Cp. The protrusions Cp include, for example, a silkscreen Sk. An example will now be described in which the protrusions Cp are the silkscreen Sk.

FIG. 12 is a schematic plan view illustrating a portion of the substrate.

As illustrated in FIG. 12, the multiple protrusions Cp (in the example, the silkscreen Sk) are located at the periphery of the pad P1. The distance information C72 is, for example, a shortest distance Dm between a center Plc of the pad P1 and the protrusions Cp. In other words, the distance information C72 is the distance between the center Plc and the protrusion Cp most proximate to the center P1c. The distance information C72 is not limited to the shortest distance Dm itself, and there are cases where the distance information C72 may be a distance corresponding to the shortest distance Dm such as, for example, the distance between the pad P1 and the protrusion Cp most proximate to the pad P1. For example, the distance information C72 may be the shortest distance between the protrusion Cp and the edge of the pad P1.

For example, the distance information C72 is obtained from the design information of the substrate S1. For example, based on the design information of the substrate S1, the shortest distance Dm can be calculated based on the coordinates of the pad P1 and the position and/or shape of the silkscreen Sk (e.g., a binarized image of the silkscreen Sk on the substrate).

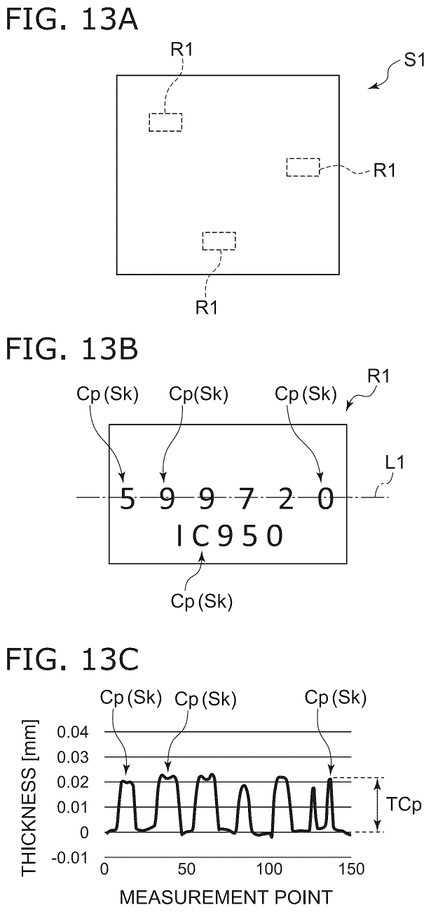

FIGS. 13A and 13B are schematic plan views illustrating portions of the substrate; and FIG. 13C is a graph illustrating an unevenness of the substrate.

Although multiple pads, the silkscreen Sk, wiring parts, etc., are located on the surface of the substrate S1, such components are not illustrated in FIG. 13A for simplicity. FIG. 13B is an enlarged view of one of multiple regions R1 illustrated in FIG. 13A. The protrusions Cp cause an unevenness in the substrate surface along a straight line such as a line L1 illustrated in FIG. 13B. FIG. 13C is an example of the unevenness along a straight line of the substrate surface measured using a three-dimensional profilometer.

The thickness information C71 is, for example, a thickness TCp of the protrusion Cp (the height of the silkscreen Sk) as illustrated in FIG. 13C. The thickness TCp of the protrusion Cp may be based on actual measured values or may be based on the design information of the substrate S1.

The thickness information C71 is not limited to the thickness of the protrusion Cp most proximate to the pad P1, and may be a value corresponding to the thickness of the protrusion Cp located at the periphery of the pad P1. For example, the multiple regions R1 on the substrate S1 each include one or multiple protrusions Cp. The thickness information C71 may be an average value of the thicknesses (the actual measured values) of the multiple protrusions Cp included in the multiple regions R1. In the example, the thickness information C71 is the average thickness of the multiple protrusions Cp inside three regions R1. The size of one region R1, the positions of the regions R1, and the number of the regions R1 are not particularly limited and may be appropriately determined.

The image entropy C73 may be the image entropy calculated based on an image in which the protrusions Cp are extracted from an image of the substrate S1 by using a method similar to that described with reference to FIG. 7 above. For example, when the protrusions Cp are the silkscreen Sk, the image entropy C73 is the image entropy described with reference to FIG. 7.

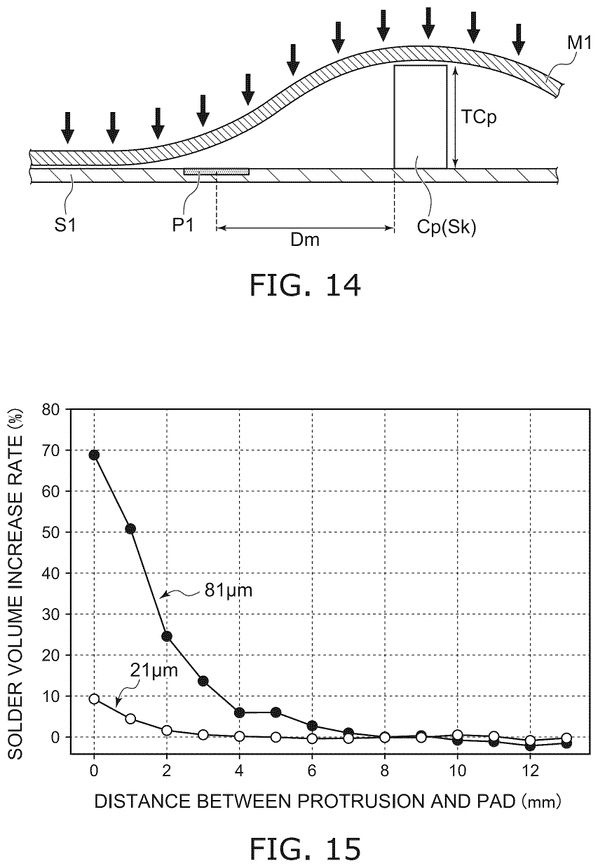

FIG. 14 is a schematic view illustrating a substrate and a stencil in the stencil printing process.

As illustrated in FIG. 14, when the stencil M1 is disposed on the substrate S1, the adhesion between the substrate S1 and the stencil M1 changes according to the unevenness due to the protrusion Cp on the substrate S1. For example, the distance between the pad P1 and the stencil M1 changes. Therefore, the volume of the solder paste to be printed changes according to the unevenness information C70 related to the protrusion Cp located on the substrate S1.

FIG. 15 is a graph illustrating the relationship between the distance between a protrusion and a pad and the increase rate of the volume of solder paste.

In FIG. 15, the increase rate is the increase rate of the volume of the solder paste printed on the pad P1 when referenced to the case where there was no protrusion Cp (or when the protrusion Cp was sufficiently distant to the pad P1). FIG. 15 shows data when the thickness of the protrusion Cp (the silkscreen Sk) was 21 μm and when the thickness of the protrusion Cp (the silkscreen Sk) was 81 μm.

As in FIG. 15, the volume of the solder paste that was printed increased as the distance between the protrusion Cp and the pad P1 decreased. In particular, the increase rate of the volume was greater when the protrusion Cp was thicker.

In contrast, in the example of FIG. 11, the printing condition 16 includes the substrate information C7 that includes the unevenness information C70. By considering the unevenness information C70, the prediction accuracy when predicting the volume of the solder paste to be printed can be further increased.

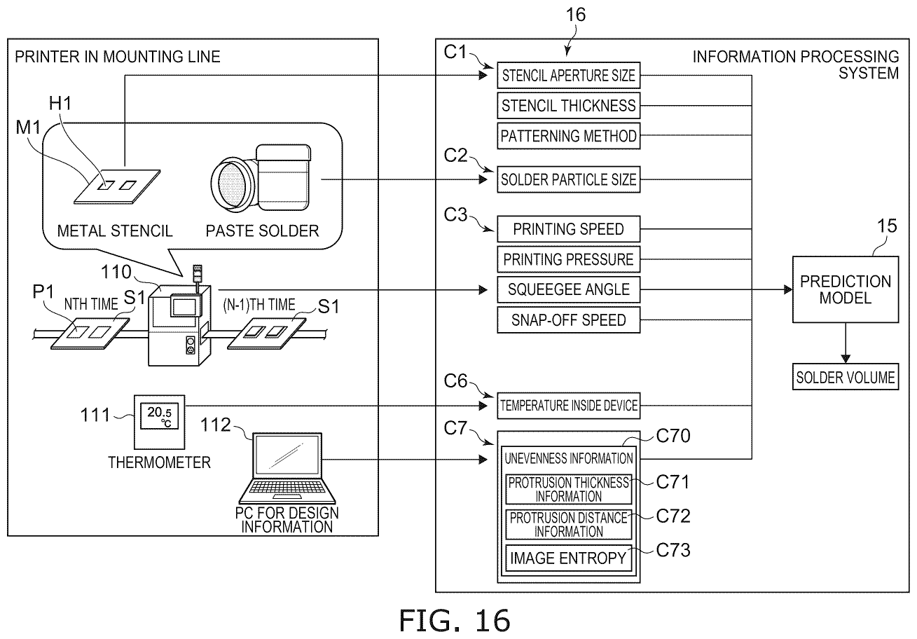

FIG. 16 is a schematic view illustrating another example of a prediction performed by the result prediction device according to the embodiment.

This example differs from the example described with reference to FIG. 11 in that the printing condition 16, which is the input of the prediction model 15, does not include the volume information C4 and the printing sequence C5.

In the example as well, the printing condition 16 includes the substrate information C7 that includes the unevenness information C70. The prediction accuracy can be increased thereby. Furthermore, when the printing condition 16 does not include the volume information C4, it is unnecessary to acquire the previous printing result of the printing, and so the volume of the solder paste can be predicted with high accuracy even for, for example, the initial printing.

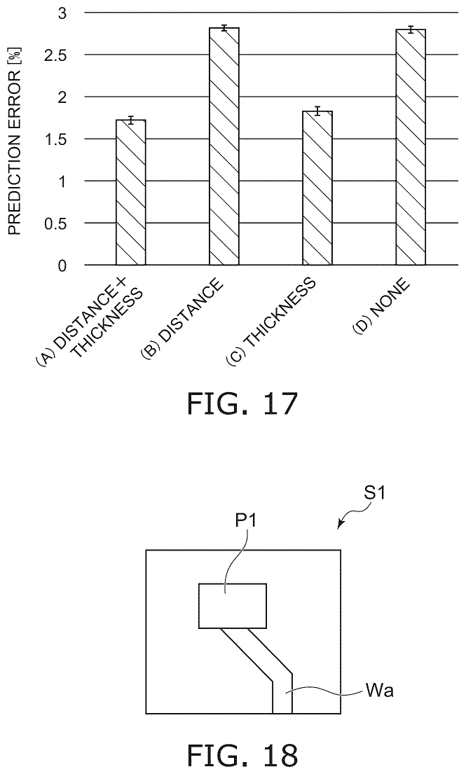

FIG. 17 is a graph illustrating the prediction error of the volume of the printed solder paste.

“(A) Distance+thickness”, “(B) Distance”, “(C) Thickness”, and “(D) None” are respectively the case where the input of the prediction model 15 includes the thickness information C71 and the distance information C72, the case where the distance information C72 is included, the case where the thickness information C71 is included, and the case where the unevenness information C70 is not included. Each input of the prediction model 15 includes the stencil information C1, the solder paste information C2, and the printing parameter C3, but does not include the volume information C4 and the printing sequence C5.

The prediction error for “(A) Distance+thickness” was about 40% less than “(D) None”. When the input of the prediction model 15 includes the printing condition 16 that includes the unevenness information C70, the prediction error can be less than a model of which the input does not include the unevenness information C70.

FIG. 18 is an enlarged schematic plan view illustrating a portion of the substrate.

The substrate S1 may include an outer-layer circuit. As illustrated in FIG. 18, the outer-layer circuit includes a wiring part Wa protruding upward from the substrate surface.

Although an example is described above in which the protrusion Cp is the silkscreen Sk, the protrusion Cp is not necessarily the silkscreen Sk. For example, the protrusion Cp may be the wiring part Wa located on the surface of the substrate S1. Or, an intersection between the silkscreen Sk and the wiring part Wa (a portion at which the silkscreen Sk and the wiring part Wa overlap each other in the thickness direction perpendicular to the substrate surface) may be taken as the protrusion Cp.

For example, both the silkscreen Sk and the wiring part Wa may be taken as the protrusions Cp. In other words, the multiple protrusions Cp may include multiple first protrusions (e.g., the silkscreen Sk) and multiple second protrusions (e.g., the wiring parts Wa). In such a case, the thickness information C71 may include at least one of first thickness information related to the thickness of the first protrusion or second thickness information related to the thickness of the second protrusion. The distance information C72 may include at least one of first distance information corresponding to the distance between the pad and the first protrusion or second distance information corresponding to the distance between the pad and the second protrusion. The image entropy may be calculated based on an image in which at least one of the first protrusion or the second protrusion is extracted. Or, the unevenness information C70 may include first image entropy calculated based on an image of the first protrusion, and second image entropy calculated based on an image of the second protrusion.

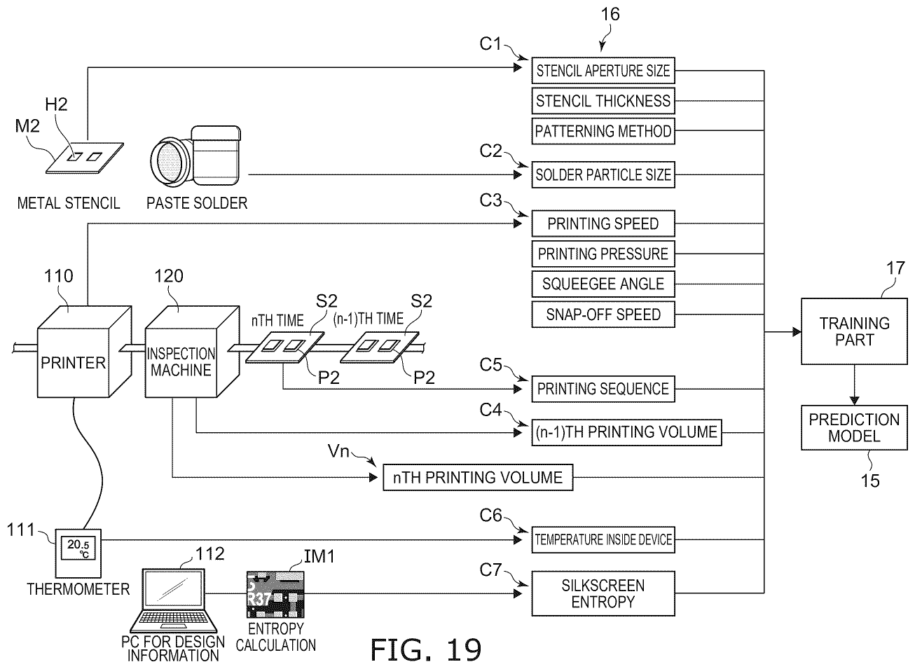

FIG. 19 is a schematic view illustrating training of a prediction model.

The printing result prediction device 100 may include a training part 17 that enables machine learning of the prediction model 15. The training part 17 uses machine learning to pre-generate the prediction model 15 before predicting the volume of the solder paste.

The training part 17 is, for example, a computer including a deep learning program. The prediction model 15 is, for example, a model trained by a neural network or random forests.

The prediction model 15 is trained to be able to output the predicted value of the volume of the printed solder paste based on the input of the printing condition. A known technique is applicable as appropriate to the machine learning.

Specifically, for example, multiple stencil printing processes are performed beforehand using one or multiple stencils M2. That is, the printer 110 performs the stencil printing process of printing solder paste on a pad P2 of a substrate S2 by filling the solder paste into a stencil aperture H2 of the stencil M2 disposed on the substrate S2. The substrate S2, the stencil M2, the stencil aperture H2, and the pad P2 are, respectively, examples of the substrate S, the stencil M, the stencil aperture H, and the pad P described with reference to FIGS. 2A to 3C. The stencil M2 and the substrate S2 that are used in the stencil printing process beforehand may be the same as (or may have the same specifications as) or may be different from the stencil M1 and the substrate S1 used in the stencil printing process of which the printing result is predicted as described with reference to FIG. 4 (the stencil printing process that prints the solder paste of which the volume is predicted).

The training part 17 trains the relationship between the printing conditions of the stencil printing processes beforehand and the volumes of the solder paste printed by the stencil apertures H2 of the stencils M2 used in the stencil printing processes beforehand. In other words, for example, the training part 17 trains by using, as teaching data, the printing condition of the stencil printing process using the stencil aperture H2 of the stencil M2 for the nth time (n being an integer not less than 2) and a volume Vn of the solder paste printed by the stencil aperture H2 of the stencil M2 by the nth stencil printing process using the stencil M2.

The printing condition related to the nth stencil printing process using the stencil M2 includes, for example, (1) the stencil information C1 related to the stencil M2, (2) the solder paste information C2 related to the solder paste used in the nth stencil printing process using the stencil M2, (3) the printing parameter C3 of the operation of the printer 110 in the nth stencil printing process using the stencil M2, (4) the volume information C4 of the volume of the solder paste printed by the stencil aperture H2 of the stencil M2 in the (n−1)th stencil printing process using the stencil M2, and (5) the printing sequence C5 indicating the number of uses of the stencil M2 in the nth stencil printing process using the stencil M2 (in other words, the information indicating that the stencil printing process is using the stencil M2 for the nth time). The printing condition related to the nth stencil printing process using the stencil M2 further includes (6) the environmental information C6 of the stencil printing process and (7) the substrate information C7 related to the substrate S2 used in the stencil printing process.

For example, the substrate information C7 may include the unevenness information C70.

As described with reference to the example of FIG. 16, the printing condition 16 may include the substrate information C7 that includes the unevenness information C70 without including the volume information C4 and the printing sequence C5. In such a case, for example, the training part 17 trains the relationship between the printing conditions of multiple previous stencil printing processes and the volumes of the solder paste printed by the stencil apertures H2 of the stencils M2 of the stencil printing processes at the printing conditions. The printing conditions of the previous stencil printing processes include, for example, (1) the stencil information C1 related to the stencil M2 used in the stencil printing process, (2) the solder paste information C2 related to the solder paste used in the stencil printing process, (3) the printing parameter C3 of the operation of the printer 110 of the stencil printing process, and (4) the substrate information C7 that includes the unevenness information C70 of the substrate S2 used in the stencil printing process. When multiple stencil printing processes are performed using one printing condition, the average value of the multiple stencil printing processes may be used as the volume of the solder paste to be trained.

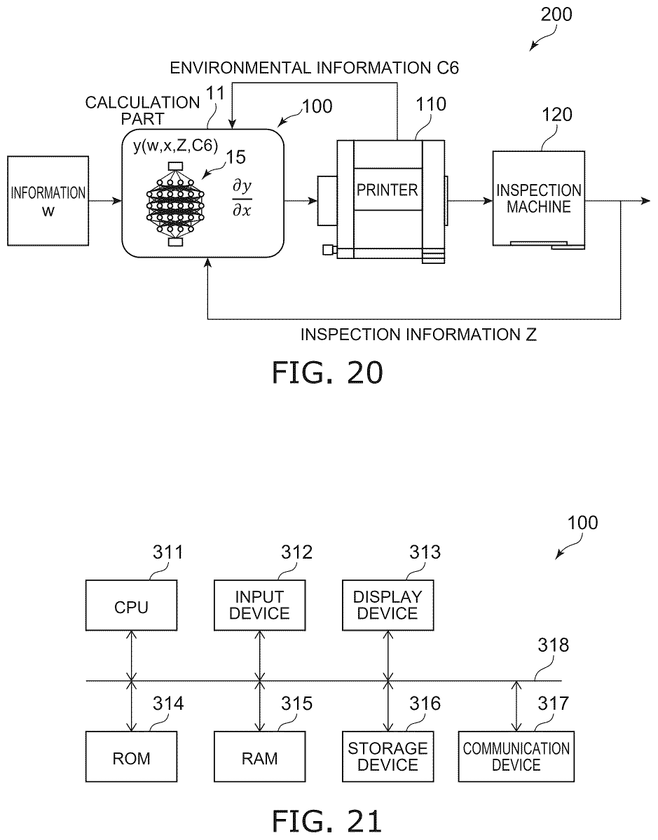

FIG. 20 is a schematic view illustrating an operation of a printing system according to an embodiment.

As illustrated in FIG. 20, the acquisition part 10 of the printing result prediction device 100 (see FIG. 1) acquires inspection information Z from the inspection machine 120. The inspection information Z includes the volume information C4 (see FIG. 4) of the volume of the solder paste printed in the previous stencil printing process. The acquisition part 10 of the printing result prediction device 100 also acquires the environmental information C6 such as the temperature, etc. Furthermore, information w is input to the printing result prediction device 100. The information w includes the stencil information C1, the solder paste information C2, the substrate information C7, etc., described with reference to FIG. 4.

The calculation part 11 of the printing result prediction device 100 acquires the printing parameter C3 and the printing sequence C5 described with reference to FIG. 4. The calculation part 11 predicts the volume of the printed solder paste in the next stencil printing process by using the trained prediction model 15 based on the information w, the printing parameter C3, the volume information C4, and the printing sequence C5.

The calculation part 11 inputs multiple printing conditions 16 to the prediction model 15 and predicts the volumes of the solder paste to be printed when the next stencil printing process is performed for each of the input printing conditions 16. The multiple printing conditions 16 that are input to the prediction model 15 are conditions such that the printing parameter C3 is changed. That is, for example, the multiple printing conditions 16 used to predict the volume of the printed solder paste by the same stencil aperture H have different printing parameters C3, but otherwise have the same conditions.

For example, the calculation part 11 calculates print quality y that is based on the prediction result and has the printing parameter C3 as a variable x. The calculation part 11 determines the printing parameter C3 of the next stencil printing process based on the change of the print quality y when the printing parameter C3 (the variable x) is changed, and outputs the printing parameter C3 to the printer 110.

Thus, the printing parameter C3 of the next stencil printing process is determined based on the predicted volume of the solder paste. The printer 110 performs the next stencil printing process by an operation indicated by the printing parameter C3 of the next stencil printing process determined by the calculation part 11.

More specifically, the calculation part 11 predicts the volume of the solder paste to be printed on the multiple pads P by the multiple stencil apertures H provided in the stencil M1. For example, the acquisition part 10 acquires multiple sets of the volume information C4 of the volumes of the solder paste printed by the multiple stencil apertures H of the stencil M1 in the previous stencil printing process using the stencil M1. For each of the multiple stencil apertures H, the calculation part 11 inputs the printing condition 16 to the prediction model 15 and predicts the volumes of the solder paste to be printed when the next stencil printing process is performed using each of the multiple printing conditions 16 that are input. Multiple printing parameters C3 that are common to the multiple stencil apertures H may be included in the multiple printing conditions 16 (the multiple printing parameters C3) input to the prediction model 15. Then, based on the prediction result, for example, the calculation part 11 determines the printing parameter C3 included in one of the multiple printing conditions 16 to be the printing parameter C3 of the next stencil printing process.

The print quality y is, for example, a parameter that represents the overall print quality of the solder paste printed on the multiple pads P present on the substrate S1. More specifically, for example, the print quality y can be “the number of pads on which solder paste determined to be good is printed”, etc. The goodness determination is the determination of whether or not the volume of the printed solder paste satisfies a prescribed reference. Although the prescribed reference is, for example, a printing transfer efficiency of not less than 95% and not more than 100%, the prescribed reference is not limited thereto, and may be determined as appropriate. Or, the print quality y may be “the total of the deviations of the printing transfer efficiencies from 100% for the pads on the substrate”. In other words, the absolute value of the difference between the printing transfer efficiency (%) and 100% for each pad may be used as the deviation of the printing transfer efficiency of the pad, and the total of the deviations of the printing transfer efficiencies of the multiple pads may be used as the print quality y.

The method of determining the printing parameter C3 employed in the next stencil printing process based on the print quality y can be, for example, a brute-force method, a steepest descent method, etc. In the brute-force method, the print quality y is calculated for all settable printing parameters C3 of the printer 110; and the printing parameter C3 having the best print quality y (e.g., the printing parameter C3 at which the print quality y is greatest) is extracted. In the steepest descent method, first, the print quality y is calculated using the printing parameter C3 having a provisional value as an input, and the printing parameter C3 having the provisional value is updated to improve the print quality y based on the gradient of the print quality y when the printing parameter C3 is changed from the provisional value. By repeating such an update, the printing parameter C3 that obtains a better print quality y than the prescribed reference value is calculated.

The print quality y described above and the method of determining the printing parameter C3 employed in the next stencil printing process based on the print quality y are examples and are not limited to those described above.

According to the printing system 200 according to the embodiment, for example, the printing parameter C3 can be appropriately updated to correspond to a change of the temperature or a change of the state of the side surface of the stencil aperture H of the stencil M during production of the substrate on which the solder paste is printed. For example, the appropriate printing parameter C3 can be automatically calculated based on information of the object to be printed. By predicting the print quality by using the printing result prediction device 100, for example, the appropriate printing parameter C3 can be set even without setting up conditions by operating the actual line. For example, the appropriate printing parameter C3 can be set independently of the experience of the user. For example, the time necessary to set the printing parameter C3 can be reduced.

FIG. 21 is a schematic view illustrating a configuration of the printing result prediction device according to the embodiment.

As an example, the printing result prediction device 100 according to the embodiment above is realized by a hardware configuration similar to a general computer (information processing device). The printing result prediction device 100 includes a CPU (Central Processing Unit) 311, an input device 312, a display device 313, ROM (Read Only Memory) 314, RAM (Random Access Memory) 315, a storage device 316, a communication device 317, and a bus 318. Each component is connected by the bus 318.

The CPU 311 comprehensively controls operations of the components included in the printing result prediction device 100 by performing various processing in collaboration with various programs prestored in the ROM 314 or the storage device 316. In the processing, the CPU 311 uses a prescribed region of the RAM 315 as a work region. The CPU 311 realizes the input device 312, the display device 313, the communication device 317, etc., in collaboration with programs prestored in the ROM 314 or the storage device 316.

The input device 312 includes, for example, at least one of a keyboard, a mouse, or a touch panel. The input device 312 accepts information input from a user as an instruction signal, and outputs the instruction signal to the CPU 311. The display device 313 is, for example, a monitor. The display device 313 outputs various information based on the signals output from the CPU 311 in a viewable fashion.

The ROM 314 non-rewritably stores programs, various setting information, etc., used to control the printing result prediction device 100. The RAM 315 is a volatile storage medium such as SDRAM (Synchronous Dynamic Random Access Memory), etc. The RAM 315 functions as a work region of the CPU 311. Specifically, the RAM 315 functions as a buffer or the like that temporarily stores various variables, parameters, etc., used by the printing result prediction device 100.

The storage device 316 is a rewritable recording device such as a storage medium based on a semiconductor such as flash memory or the like, a magnetically or optically recordable storage medium, etc. The storage device 316 stores programs, various setting information, and the like used to control the printing result prediction device 100, the trained prediction model, a database that records the model names, specifications, and the like of the stencil, etc. The communication device 317 is used to transmit and receive information by communicating with external devices.

For example, the CPU 311, the ROM 314, and the RAM 315 function as the calculation part 11 (see FIG. 1); the input device 312 and the communication device 317 function as the acquisition part 10 (see FIG. 1); and the storage device 316 functions as the storage part 13 (see FIG. 1).

The embodiments may include the following configurations (for example, technical proposals).

### Configuration 1

A printing result prediction device configured to predict a volume of solder paste printed by a printer onto a substrate, the printer printing the solder paste by filling the solder paste into a stencil aperture of a stencil disposed on the substrate, the device comprising:
a calculation part configured to
   input a printing condition to a prediction model trained by machine learning, and
   predict a volume of solder paste printed by the stencil aperture of the stencil in a next printing using the input printing condition,
the printing condition including
   stencil information related to the stencil used to print,
   solder paste information related to the solder paste used to print,
   substrate information including unevenness information related to a protrusion on the substrate used to print, and
   a printing parameter of an operation of the printer when printing.

### Configuration 2

The device according to Configuration 1, wherein
the prediction model is a model trained using a neural network or random forests.

### Configuration 3

The device according to Configuration 1 or 2, wherein
the substrate used to print includes a pad on which solder paste is printed by the stencil aperture, and
the unevenness information includes at least one of thickness information related to a thickness of the protrusion, distance information corresponding to a distance between the protrusion and the pad, or image entropy calculated based on an image including the protrusion.

### Configuration 4

The device according to any one of Configurations 1 to 3, wherein
the protrusion includes a silkscreen.

### Configuration 5

The device according to any one of Configurations 1 to 4, wherein
the protrusion includes a wiring part of an outer-layer circuit.

### Configuration 6

The device according to any one of Configurations 3 to 5, wherein
the thickness information is an average of thicknesses of a plurality of the protrusions located in a plurality of regions on the substrate.

### Configuration 7

The device according to any one of Configurations 3 to 6, wherein
the distance information is a shortest distance between the protrusion and a center of the pad.

### Configuration 8

The device according to any one of Configurations 1 to 7, further comprising:
an acquisition part configured to acquire volume information of a volume of solder paste printed by the stencil aperture of the stencil in a previous printing using the stencil,
the printing condition including
   the volume information of the volume of the solder paste printed in the previous printing, and
   a printing sequence indicating a number of uses of the stencil used to print.

### Configuration 9

A printing system, comprising:
the device according to Configuration 8;
the printer; and
an inspection machine configured to detect the volume of the printed solder paste,
the acquisition part acquiring the volume information of the volume of the solder paste printed in the previous printing from the inspection machine,
the calculation part determining the printing parameter for the next printing based on the predicted volume of the solder paste,
the printer performing the next printing by an operation indicated by the printing parameter for the next printing determined by the calculation part.

According to embodiments, a printing result prediction device and a printing system that can increase the prediction accuracy of the volume of solder paste to be printed can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A printing result prediction device configured to predict a volume of solder paste printed by a printer onto a substrate, the printer printing the solder paste by filling the solder paste into a stencil aperture of a stencil disposed on the substrate, the device comprising:
a calculation part configured to
input a printing condition to a prediction model trained by machine learning, and
predict a volume of solder paste printed by the stencil aperture of the stencil in a next printing using the input printing condition,
the printing condition including
stencil information related to the stencil used to print,
solder paste information related to the solder paste used to print,
substrate information including unevenness information related to a protrusion on the substrate used to print, and
a printing parameter of an operation of the printer when printing.

2. The device according to claim 1, wherein
the prediction model is a model trained using a neural network or random forests.

3. The device according to claim 1, wherein
the substrate used to print includes a pad on which solder paste is printed by the stencil aperture, and
the unevenness information includes at least one of thickness information related to a thickness of the protrusion, distance information corresponding to a distance between the protrusion and the pad, or image entropy calculated based on an image including the protrusion.

4. The device according to claim 1, wherein
the protrusion includes a silkscreen.

5. The device according to claim 1, wherein
the protrusion includes a wiring part of an outer-layer circuit.

6. The device according to claim 3, wherein
the thickness information is an average of thicknesses of a plurality of the protrusions located in a plurality of regions on the substrate.

7. The device according to claim 3, wherein
the distance information is a shortest distance between the protrusion and a center of the pad.

8. The device according to claim 1, further comprising:
an acquisition part configured to acquire volume information of a volume of solder paste printed by the stencil aperture of the stencil in a previous printing using the stencil,
the printing condition including
the volume information of the volume of the solder paste printed in the previous printing, and
a printing sequence indicating a number of uses of the stencil used to print.

9. A printing system, comprising:
the device according to claim 8;
the printer; and
an inspection machine configured to detect the volume of the printed solder paste,
the acquisition part acquiring the volume information of the volume of the solder paste printed in the previous printing from the inspection machine,
the calculation part determining the printing parameter for the next printing based on the predicted volume of the solder paste,
the printer performing the next printing by an operation indicated by the printing parameter for the next printing determined by the calculation part.
